(19) United States
(12) Patent Application Publication
(10) Pub. No.: US 2026/0107673 A1
(43) Pub. Date: Apr. 16, 2026

(54) ELECTRONIC DEVICE AND METHOD FOR MANUFACTURING THE SAME

(71) Applicant: Samsung Display Co., Ltd., Yongin-si (KR)

(72) Inventors: KUHYUN KANG, Yongin-si (KR); HO YUN KANG, Yongin-si (KR); SANG-PIL PARK, Yongin-si (KR); GIHAN LEEM, Yongin-si (KR); YOUNGKYUN OH, Yongin-si (KR); YOUNGJIN OH, Yongin-si (KR); YONG-HEE LEE, Yongin-si (KR); KYOUNGSEOK CHO, Yongin-si (KR)

(21) Appl. No.: 19/265,193

(22) Filed: Jul. 10, 2025

(30) Foreign Application Priority Data
Oct. 11, 2024 (KR) 10-2024-0138707

(51) Int. Cl. H10K 71/00; H10K 59/40; H10K 59/80

(52) U.S. Cl. CPC H10K 71/851; H10K 59/40; H10K 59/87; H10K 59/8791

(57) ABSTRACT

An electronic device includes a display panel including an active area, in which a plurality of pixels are arranged, and a peripheral area being adjacent to the active area, a window on the display panel, a housing on a lower side of the display panel and accommodating the display panel, an optical layer on the window and including a plurality of layers, and an adhesion layer between the window and the optical layer and attaching the window and the optical layer. The plurality of layers includes a first layer, a second layer on the first layer, and a third layer on the second layer, and a side surface of the third layer includes a stepped part overlapping the peripheral area.

### CROSS-REFERENCE TO RELATED APPLICATION

The present application claims priority to and the benefit of Korean Patent Application No. 10-2024-0138707, filed on Oct. 11, 2024, in the Korean Intellectual Property Office, the entire disclosure of which is incorporated herein by reference.

### BACKGROUND

### 1. Field

One or more embodiments of the present disclosure relate to an electronic device, and a method for manufacturing the same, for example, relate to an electronic device having an improved reliability.

### 2. Description of the Related Art

An electronic device, such as a television, a monitor, a smartphone, and/or a tablet, provides an image to a user. The electronic device may include a display device that include a display panel to show (display) the image. Various types (kinds) of display panels, such as liquid crystal display panels, organic light-emitting display panels, electro-wetting display panels, and/or electrophoretic display panels, have been developed and utilized. Additionally, the display device may include a window for protecting the display panel. The window may be attached to the display panel through a laser cutting process.

### SUMMARY

One or more aspects of embodiments of the present disclosure are directed toward an electronic device, and a method for manufacturing the same. Additional aspects will be set forth in part in the description which follows and, in part, will be apparent from the description, or may be learned by practice of the presented embodiments.

According to one or more embodiments of the present disclosure, an electronic device includes a display panel including an active area, in which a plurality of pixels are arranged, and a peripheral area being adjacent to the active area, a window on (e.g., arranged) on the display panel, a housing on (e.g., arranged on) a lower side of the display panel and accommodating the display panel, an optical layer on (e.g., arranged on) the window and including a plurality of layers, and an adhesion layer between (e.g., arranged between) the window and the optical layer and attaching the window and the optical layer, wherein the plurality of layers include a first layer, a second layer on (e.g., arranged on) the first layer, and a third layer on (e.g., arranged on) the second layer, and a side surface of the third layer includes a stepped part overlapping the peripheral area.

The stepped part may include a first surface inclined at a first angle with respect to an upper surface of the window and a second surface inclined at a second angle with respect to the upper surface of the window, the second angle being different from the first angle.

In one or more embodiments, at least one of the first surface or the second surface may include a flat surface.

In one or more embodiments, at least one of the first surface or the second surface may include a curved surface.

The stepped part further may include a third surface connected to the first surface or the second surface, and inclined with respect to the upper surface of the window at a third angle, the third angle being different from an angle of a connected one of the first surface or the second surface with respect to the upper surface of the window. For example, the third angle is different from the angle of the connected first surface or second surface with respect to the upper surface of the window.

The third layer may be provided with a plurality of layers, the plurality of layers may include a triacetylcellulose layer, a polyolefin film on (e.g., arranged on) the triacetylcellulose layer, and a protective film on (e.g., arranged on the polyolefin film, and the stepped part may be defined on the triacetylcellulose layer.

A side surface of the second layer may be further spaced and/or apart (e.g., spaced apart or separated) from the active area than a side surface of the first layer.

According to one or more embodiments of the present disclosure, a window module includes a window including a first area and a second area around (e.g., surrounding) a periphery of the first area on a plane (e.g., in plan view), an optical layer including a first layer, a second layer on (e.g., arranged on) the first layer, and a third layer on (e.g., arranged on) the second layer, and an adhesion layer between (e.g., arranged between) the window and the optical layer and attaching the window and the optical layer, wherein a groove includes a first part passing through the third layer and a second part passing through the first layer and the second layer and exposing at least a portion of the adhesion layer, and wherein the first part includes at least one stepped part. For example, the groove includes the first part passing through the third layer and the second part passing through the first and second layers, the second part exposing at least a portion of the adhesion layer. The first part includes the at least one stepped part.

A width of the first part may be greater than a width of the second part, on a cross section.

The stepped part may include a curved surface.

A surface of the third layer, which defines the groove, may include a protruding portion, and the protruding portion may protrude toward an upper surface of the third layer.

According to one or more embodiments of the present disclosure, a method for manufacturing an electronic device includes providing a display panel, providing a window including a first area and a second area around (e.g., surrounding) a periphery of the first area on a plane (in plan view), forming a preliminary window module by sequentially laminating an adhesion layer and an optical layer on the window, forming a window module by cutting the preliminary window module, and combining the display panel and the window module, wherein the forming of the window module by cutting the preliminary window module includes a first irradiation operation of irradiating a first laser beam along a first irradiation line defined along the second area, a second irradiation operation of irradiating a second laser beam along a second irradiation line spaced and/or apart (e.g., spaced apart or separated) from the first irradiation line, and a third irradiation operation of irradiating a third laser beam along a third irradiation line defined between the first irradiation line and the second irradiation line, and the second irradiation line is further spaced and/or apart (e.g., spaced apart or separated) from the first area than the first irradiation line. For example, the second irradiation line is positioned farther away from the first area than the first irradiation line. This refers to that the distance from the first area to both the first and second irradiation lines, the second irradiation line will be at a greater distance from the first area compared to the first irradiation line.

The second irradiation operation may be progressed after the first irradiation operation, and the third irradiation operation may be progressed after the second irradiation operation.

A third depth which the third laser beam reaches may be greater than a first depth which the first laser beam reaches and a second depth which the second laser beam reaches.

In the third irradiation operation, a depth which the third laser beam reaches may be smaller than a depth of a lower surface of the adhesion layer, e.g., relative to an upper surface of the optical layer.

The optical layer may include a phase delay layer, an adhesion member on (e.g., arranged on) the phase delay layer, and a polarizing plate on (e.g., arranged on) the adhesion member, and in the first irradiation operation, the phase delay layer and the adhesion member may not be cut.

In the first irradiation operation, a depth which the first laser beam reaches may be smaller than a thickness of the polarizing plate.

The optical layer may include a plurality of layers, the plurality of layers may include a triacetylcellulose layer, a polyolefin film on (e.g., arranged on) the triacetylcellulose layer, and a protective film on (e.g., arranged on) the polyolefin film, and the first laser beam may pass through the polyolefin film and the protective film and may exposes at least a portion of the triacetylcellulose layer.

A distance between the first irradiation line and the second irradiation line may be smaller than a half of a diameter of each of the first laser beam, the second laser beam, and the third laser beam.

Power of the third laser beam may be lower than power of each of the first laser beam and the second laser beam.

### BRIEF DESCRIPTION OF DRAWINGS

The accompanying drawings are included to provide a further understanding of the disclosure, and are incorporated in and constitute a part of this disclosure. The drawings illustrate embodiments of the present disclosure and, together with the description, serve to explain principles of the disclosure. The above and other objects and features of the present disclosure will become apparent by describing in example embodiments thereof with reference to the accompanying drawings.

FIG. 1A is a perspective view of an electronic device according to one or more embodiments of the present disclosure.

FIG. 1B is a block diagram of an electronic device according to one or more embodiments of the present disclosure.

FIG. 2 is an exploded perspective view of an electronic device according to one or more embodiments of the present disclosure.

FIG. 3 is a view illustrating a cross section of the electronic device illustrated in FIG. 1A by way of example.

FIG. 4 is a view illustrating a cross section of a display panel illustrated in FIG. 3 by way of example.

FIG. 5 is an enlarged cross-sectional view illustrating a portion of a window module according to one or more embodiments of the present disclosure.

FIG. 6 is an enlarged cross-sectional view illustrating a portion of a window module according to one or more embodiments of the present disclosure.

FIG. 7 is an enlarged cross-sectional view illustrating a portion of a window module according to one or more embodiments of the present disclosure.

FIG. 8 is an enlarged cross-sectional view illustrating a portion of a window module according to one or more embodiments of the present disclosure.

FIG. 9 is an enlarged cross-sectional view illustrating a portion of a window module according to one or more embodiments of the present disclosure.

FIG. 10 is an enlarged cross-sectional view illustrating a portion of a window module according to one or more embodiments of the present disclosure.

FIG. 11A is a plan view of a window module according to one or more embodiments of the present disclosure.

FIG. 11B-11I are cross-sectional views illustrating some of operations of a method for manufacturing an electronic device according to one or more embodiments of the present disclosure.

FIG. 12A-12C are cross-sectional views illustrating some of operations of a method for manufacturing an electronic device according to one or more embodiments of the present disclosure.

### DETAILED DESCRIPTION

Embodiments of the present disclosure may be modified and practiced in many alternate forms, and thus example embodiments will be exemplified in the drawings and described in more detail. It should be understood, however, that it is not intended to limit the disclosure to the particular forms disclosed, but rather, is intended to cover all modifications, equivalents, and alternatives falling within the spirit and scope of the disclosure.

In the disclosure, if (e.g., when) it is mentioned that a component (or an area, a layer, a part, and/or the like) is “on”, “arranged on”, “connected to”, or “coupled to” another component, it refers to that the former component may be directly arranged on, connected to, or coupled to the latter component or a third component may be arranged between the components.

The same or like reference numerals denote the same or like components in the present disclosure. Furthermore, in the drawings, thicknesses, ratios, dimensions of the components may be exaggerated for an effective description of the technical contents. The term “and/or” or “or” may include one or more combinations that may be defined by the associated components.

Furthermore, in describing the one or more suitable components, the terms, such as “first” and “second” may be used, but embodiments of the present disclosure are not limited by the terms. The terms are simply for distinguishing the components. For example, a first component may be named a second component, and similarly a second component also may be named a first component while not departing from the scope of the present disclosure. As used herein, a singular expression includes a plural expression unless an exemption is explicitly described in the context. For example, the singular forms “a,” “an,” and “the” are intended to include the plural forms as well, unless the context clearly indicates otherwise. Further, the use of “may” when describing embodiments of the present disclosure refers to “one or more embodiments of the present disclosure.”

Furthermore, the terms, such as “under”, “below”, “on”, and “above”, are used to describe an associative relationship between the components illustrated in the drawings. The terms are relative concepts, and are described with respect to directions indicated in the drawings.

Unless otherwise defined, all terms, including technical and scientific terms, used herein have the same meaning as commonly understood by those skilled in the art to which the present disclosure pertains. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein.

When the terms, such as “comprise(s)/comprising” and/or “include(s)/including” and/or “has(have)/having, are used in the disclosure, it should be understood that they specify presence of the stated features, numbers, steps, operations, components, parts, and/or one or more (e.g., any suitable) combinations thereof, but do not exclude presence or addition of one or more other features, numbers, steps, operations, components, parts, and/or one or more (e.g., any suitable) combinations thereof. Additionally, the terms “comprise(s)/comprising,”“include(s)/including,” “has(have)/having”, or other similar terms include or support the terms “consisting of” and “consisting essentially of,” indicating the presence of stated features, numbers, steps, operations, parts, and/or components, without or essentially without the presence of other features, numbers, steps, operations, parts, components, and/or groups thereof.

Hereinafter, example embodiments of the present disclosure will be described with reference to the drawings.

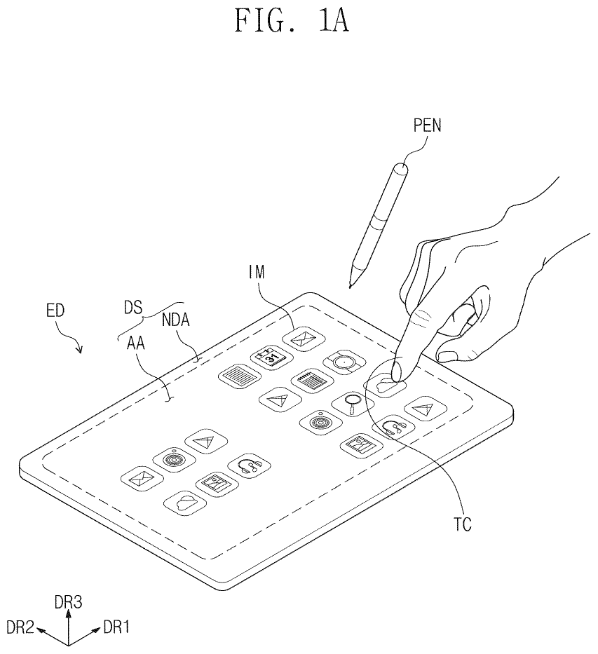

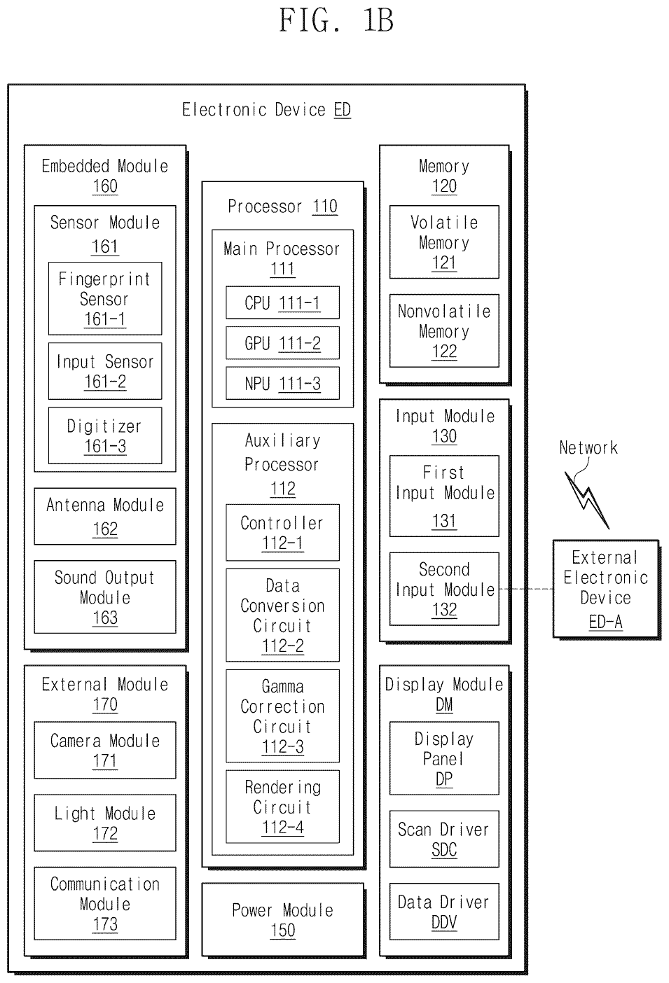

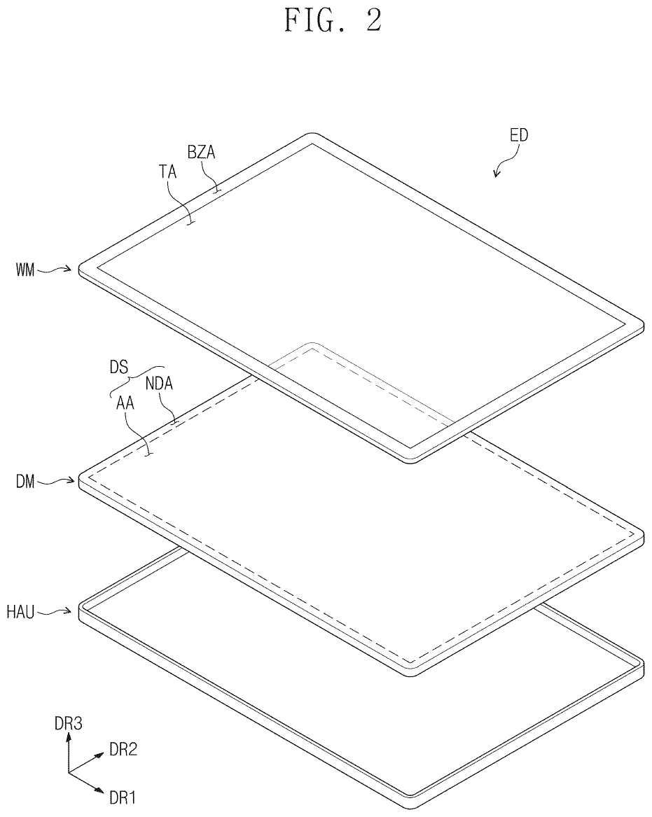

FIG. 1A is a perspective view of an electronic device according to one or more embodiments of the present disclosure. FIG. 1B is a block diagram of an electronic device according to one or more embodiments of the present disclosure. FIG. 2 is an exploded perspective view of an electronic device according to one or more embodiments of the present disclosure. In FIG. 1A and FIG. 2, it is illustrated, by way of example, that the electronic device is a tablet device. Embodiments of the present disclosure are not limited thereto.

Referring to FIG. 1A, an electronic device ED may include long sides that extend in parallel in a first direction DR1 and short sides that extend in parallel in a second direction DR2 that crosses the first direction DR1. However, this is illustrated by way of example, for example, the electronic device ED may include sides having substantially the same length with respect to each of the first and second directions DR1 and DR2, and embodiments of the present disclosure are not limited thereto.

Hereinafter, a direction that is substantially normal (e.g., perpendicular) to a plane defined by the first direction DR1 and the second direction DR2 is defined as a third direction DR3. Furthermore, in the disclosure, a meaning of “if (e.g., when) viewed on a plane” “on a plane” or “in plan view” is defined as a state, in which it is viewed from the third direction DR3.

A front surface of the electronic device ED may be defined as a display surface DS, and may have a plane defined by a first direction DR1 and a second direction DR2. An image IM that is generated by the electronic device ED may be provided to a user through the display surface DS.

Referring to FIG. 1A and FIG. 2, the display surface DS may include an active area AA and a peripheral area NDA. The active area AA may be an area that is enabled according to an electrical signal. For example, the active area AA may be an area, in which the image IM is displayed, and also is an area, in which an external input TC is sensed. The active area AA may overlap at least a portion of a transmission area TA. Accordingly, the user may visually recognize the image IM through the transmission area TA or provide an external input TC. However, this is merely an example, in one or more embodiments, an area, in which the image IM is displayed, and an area, in which the external input TC is sensed, may be separated from each other in the active area AA, and embodiments of the present disclosure are not limited thereto.

Referring to FIG. 1A and FIG. 2, the peripheral area NDA may be adjacent to the active area AA. For example, in one or more embodiments, the peripheral area NDA may be around (e.g., surround) the active area AA. In the peripheral area NDA, a driving circuit or a driving wiring line for driving the active area AA may be arranged. The peripheral area NDA may overlap at least a portion of a bezel area BZA, and components that are arranged in the peripheral area NDA may be prevented or reduced from being visually recognized from the outside, by the bezel area BZA.

The electronic device ED may sense inputs that are applied from the outside of the electronic device ED. For example, the electronic device ED may sense a first input by the external input TC and/or a second input by a touch pen PEN. The first input by the external input TC may include one or more suitable types (kinds) of external inputs, such as a part of the user's body, light, heat, and/or pressure. The touch pen PEN may be an active pen or an electromagnetic pen, but embodiments of the present disclosure are not limited thereto. The touch pen PEN may be defined as an input device, and the active area AA may provide a sensing area capable of sensing an input to a user, in addition to displaying an image.

In one or more embodiments, the electronic device ED may be a large electronic device, such as a television, a monitor, and/or an external billboard. In one or more embodiments, the electronic device ED may be a small and medium-sized electronic device, such as a personal computer, a laptop computer, a personal digital terminal, a car navigation unit, a game machine, a smartphone, a tablet, and/or a camera. However, this is merely an example, and the electronic device ED may be other display devices unless it deviates from the concept of the present disclosure.

Referring to FIG. 1B, the electronic device ED may output one or more suitable information through a display module DM in an operating system. When a processor 110 executes an application that is stored in a memory 120, the display module DM may provide application information to a user through a display panel DP.

The processor 110 may acquire an external input through an input module 130 or a sensor module 161, and may execute an application corresponding to the external input. For example, if (e.g., when) the user selects a camera icon that is displayed on the display panel DP, the processor 110 may acquire a user input through an input sensor 161-2, and may activate a camera module 171. The processor 110 may be to transmit image data corresponding to a captured image acquired through the camera module 171 to the display module DM. The display module DM may display an image corresponding to the captured image through the display panel DP.

In the above, an operation of the electronic device ED has been briefly described. Hereinafter, a configuration of the electronic device ED will be described in more detail. Some of the components of the electronic device ED, which will be described in more detail, may be integrated to be provided as one component, and one component may be provided separately as two or more components.

Referring to FIG. 1B, the electronic device ED may communicate with an external electronic device ED-A through a network (e.g., a short-distance wireless communication network or a long-distance wireless communication network). According to one or more embodiments, the electronic device ED may include a processor 110, a memory 120, an input module 130, a display module DM, a power module 150, an embedded module 160, and an external module 170. According to one or more embodiments, in the electronic device ED, at least one of (e.g., selected from among) the above-described components may not be provided, or one or more other components may be added. According to one or more embodiments, some of the above-described components (e.g., the sensor module 161, an antenna module 162, or a sound output module 163) may be integrated into another component (e.g., the display module DM).

The processor 110 may execute software to control at least one other component (e.g., a hardware or software component) of the electronic device ED that is connected to the processor 110, and may perform one or more suitable data processing or operations. According to one or more embodiments, as at least a part of data processing or operation, the processor 110 may store a command or data received from another component (e.g., the input module 130, the sensor module 161, or a communication module 173) in a volatile memory 121, and process the command or data stored in the volatile memory 121, and the result data may be stored in a nonvolatile memory 122.

The processor 110 may include a main processor 111 and an auxiliary processor 112. The main processor 111 may include one or more of a central processing unit (CPU) 111-1 or an application processor (AP). In one or more embodiments, the main processor 111 may further include one or more of a graphic processing unit (GPU) 111-2, a communication processor (CP), and an image signal processor (ISP). In one or more embodiments, the main processor 111 may further include a neural network processing unit (NPU) 111-3. The neural network processing unit/device is a processor that is specialized in the processing of an artificial intelligence model, and the artificial intelligence model may be generated through machine learning. The artificial intelligence model may include a plurality of artificial neural network layers. The artificial neural network may be one of (e.g., selected from among) a deep neural network (DNN), a convolutional neural network (CNN), a recurrent natural network (RNN), a restricted Boltzmann machine (RBM), a deep believe network (DBN), a bidirectional recurrent deep natural network (BRDN), a deep Q-network, and/or a (e.g., any suitable) combination of two or more thereof, but embodiments of the present disclosure are not limited thereto. In addition to the hardware structure, the artificial intelligence model may additionally or alternatively include a software structure. At least two of (e.g., selected from among) the above-described processing units and processors may be implemented as one integrated component (e.g., a single chip), or each may be implemented as an independent component (e.g., a plurality of chips).

The auxiliary processor 112 may include a controller 112-1. The controller 112-1 may include an interface conversion circuit and a timing control circuit. The controller 112-1 receives an image signal from the main processor 111, converts a data format of the image signal to meet an interface specification with the display module DM, and outputs image data. The controller 112-1 may output one or more suitable control signals that are necessary for driving the display module DM.

In one or more embodiments, the auxiliary processor 112 may further include a data conversion circuit 112-2, a gamma correction circuit 112-3, and a rendering circuit 112-4. The data conversion circuit 112-2 may receive image data from the controller 112-1 and compensate for the image data to display an image with a desired or suitable luminance depending on characteristics of the electronic device ED or a user's setting, or may convert the image data to reduce power consumption or compensate for an afterimage. The gamma correction circuit 112-3 may convert image data or a gamma reference voltage so that the image displayed on the electronic device ED has desired or suitable gamma characteristics. The rendering circuit 112-4 may receive the image data from the controller 112-1 and may render the image data in consideration of disposition of pixels of the display panel DP, which is applied to the electronic device ED. In one or more embodiments, at least one of the data conversion circuit 112-2, the gamma correction circuit 112-3, or the rendering circuit 112-4 may be integrated into another component (e.g., the main processor 111 or the controller 112-1). In one or more embodiments, at least one of the data conversion circuit 112-2, the gamma correction circuit 112-3, or the rendering circuit 112-4 may be integrated into a data driver DDV that will be described in more detail later.

The memory 120 may store one or more suitable data that are used by at least one component (e.g., the processor 110 or the sensor module 161) of the electronic device ED, and input or output data for a command related thereto. The memory 120 may include at least one of a volatile memory 121 or a nonvolatile memory 122.

The input module 130 may receive a command and/or data that will be used in a component (e.g., the processor 110, the sensor module 161, or the sound output module 163) of the electronic device ED from the outside (e.g., a user or an external electronic device ED-A) of the electronic device ED.

The input module 130 may include a first input module 131, to which a command or data is input, from the user and a second input module 132, to which a command or data is input, from the external electronic device ED-A. The first input module 131 may include a microphone, a mouse, a keyboard, a key (e.g., a button), or a pen (e.g., a passive pen or an active pen). The second input module 132 may support a designated protocol for connection to the external electronic device ED-A by wire or wirelessly. According to one or more embodiments, the second input module 132 may include a high definition multimedia interface (HDMI), a universal serial bus (USB) interface, a secure digital (SD) card interface, and/or an audio interface. The second input module 132 may include a connector for physical connection to the external electronic device ED-A, for example, an HDMI connector, a USB connector, an SD card connector, and/or an audio connector (e.g., a headphone connector).

The display module DM visually provides information to the user. The display module DM may include a display panel DP, a scan driver SDC, and a data driver DDV. The display module DM may further include a window, a chassis, and a bracket for protecting the display panel DP.

The display panel DP may include a liquid crystal display panel, an organic light emitting display panel, or an inorganic light emitting display panel, and the type (kind) of the display panel DP is not particularly limited. The display panel DP may be a rigid type (kind), or a flexible type (kind) that may be rolled or folded. The display module DM may further include a supporter, a bracket, and/or a heat dissipating member, which support the display panel DP.

The scan driver SDC may be mounted on the display panel DP as a driving chip. In one or more embodiments, the scan driver SDC may be integrated on the display panel DP. For example, the scan driver SDC may include an amorphous silicon TFT gate driver circuit (ASG), a low temperature polycrystalline silicon (LTPS) TFT gate driver circuit, and/or an oxide semiconductor TFT gate driver circuit (OSG), that are internalized in the display panel DP. The scan driver SDC receives a control signal from the controller 112-1, and outputs scan signals to the display panel DP in response to the control signal.

In one or more embodiments, the display panel DP may further include a light emission driver. The light emission driver outputs an emission control signal to the display panel DP in response to the control signal received from the controller 112-1. The light emission driver may be formed to be distinguished from the scan driver SDC, or may be integrated into the scan driver SDC.

The data driver DDV receives a control signal from the controller 112-1, converts image data into analog voltages (e.g., data voltages) in response to the control signal, and outputs data voltages to the display panel DP.

In one or more embodiments, the data driver DDV may be integrated into another component (e.g., the controller 112-1). Functions of the interface conversion circuit and the timing control circuit of the controller 112-1 may be integrated into the data driver DDV.

In one or more embodiments, the display module DM may further include a light emission driver and a voltage generating circuit. The voltage generating circuit may output one or more suitable voltages that are desired or required for driving the display panel DP.

The power module 150 supplies electric power to the components of the electronic device ED. In one or more embodiments, the power module 150 may include a battery for charging a power voltage. The battery may include a non-rechargeable primary battery, a rechargeable secondary battery, and/or a fuel cell. The power module 150 may include a power management integrated circuit (PMIC). The PMIC supplies desired or optimized electric power to each of the above-described modules and modules that will be described in more detail later. In one or more embodiments, the power module 150 may include a wireless power transceiving member that is electrically connected to the battery. The wireless power transceiving member may include a plurality of antenna radiators in a coil form.

In one or more embodiments, the electronic device ED may include the embedded module 160 and the external module 170. The embedded module 160 may include a sensor module 161, an antenna module 162, and a sound output module 163. The external module 170 may include a camera module 171, a light module 172, and a communication module 173.

The sensor module 161 may sense an input by a user's body or an input by a pen among the first input modules 131, and may generate an electrical signal or data value corresponding to the input. The sensor module 161 may include at least one of a fingerprint sensor 161-1, an input sensor 161-2, or a digitizer 161-3.

The fingerprint sensor 161-1 may generate a data value corresponding to the user's fingerprint. The fingerprint sensor 161-1 may include any one of an optical type (kind) or capacitive type (kind) fingerprint sensor.

The input sensor 161-2 may generate a data value corresponding to an input by a user's body or coordinate information of an input by a pen. The input sensor 161-2 generates a change in capacitance due to an input as a data value. In one or more embodiments, the input sensor 161-2 may sense an input by a passive pen or transmit and receive data to and from an active pen.

In one or more embodiments, the input sensor 161-2 may measure a bio-signal, such as a blood pressure, moisture, or body fat. For example, if (e.g., when) a part of the body of the user contacts the sensor layer or the sensing panel of the input sensor 161-2 and does not move for a specific time, the input sensor 161-2 may sense a bio-signal and output information desired by the user to the display module DM based on a change in an electric field caused by the part of the body.

The digitizer 161-3 may generate a data value corresponding to coordinate information of an input by a pen. The digitizer 161-3 generates a change amount of an electromagnetic field by an input as a data value. The digitizer 161-3 may sense an input by a passive pen or transmit and receive data to and from an active pen.

In one or more embodiments, at least one of the fingerprint sensor 161-1, the input sensor 161-2, or the digitizer 161-3 may be implemented as a sensor layer that is formed on the display panel DP through a continuous process. In one or more embodiments, the fingerprint sensor 161-1, the input sensor 161-2, and the digitizer 161-3 may be arranged on the display panel DP. In one or more embodiments, any one selected from among the fingerprint sensor 161-1, the input sensor 161-2, and the digitizer 161-3, for example, the digitizer 161-3, may be arranged under the display panel DP.

In one or more embodiments, at least two selected from among the fingerprint sensor 161-1, the input sensor 161-2, and the digitizer 161-3 may be integrated into one sensing panel through a same process. When being integrated into a single sensing panel, the sensing panel may be arranged between the display panel DP and a window arranged on the display panel DP. According to one or more embodiments, the sensing panel may be arranged on the window, and a position of the sensing panel is not particularly limited.

In one or more embodiments, at least one of the fingerprint sensor 161-1, the input sensor 161-2, or the digitizer 161-3 may be embedded in the display panel DP. For example, through the process of forming elements (e.g., a light emitting element, a transistor, and/or the like) included in the display panel DP, at least one of the fingerprint sensor 161-1, the input sensor 161-2, or the digitizer 161-3 may be concurrently (e.g., simultaneously) formed.

Furthermore, the sensor module 161 may generate an electrical signal or a data value corresponding to an internal state or an external state of the electronic device ED. In one or more embodiments, the sensor module 161 may further include, for example, a gesture sensor, a gyro sensor, a barometric pressure sensor, a magnetic sensor, an acceleration sensor, a grip sensor, a proximity sensor, a color sensor, an infrared sensor (IR) sensor, a biometric sensor, a temperature sensor, a humidity sensor, and/or an illuminance sensor.

The antenna module 162 may include one or more antennas for transmitting or receiving a signal or power to or from the outside. According to one or more embodiments, the communication module 173 may be to transmit a signal to an external electronic device through an antenna that is suitable for a communication method or may receive a signal from an external electronic device. The antenna pattern of the antenna module 162 may be integrated into one component (e.g., the display panel DP) of the display module DM, the input sensor 161-2, and/or the like.

The sound output module 163 is a device for outputting a sound signal to the outside of the electronic device ED, and may include, for example, a speaker that is used for a general purpose, such as multimedia playback or recording playback, and a receiver that is used exclusively for phone reception. According to one or more embodiments, the receiver may be formed integrally or separately from the speaker. The sound output pattern of the sound output module 163 may be integrated into the display module DM.

The camera module 171 may capture still images and moving images. According to one or more embodiments, the camera module 171 may include one or more lenses, an image sensor, and/or an image signal processor. In one or more embodiments, the camera module 171 may further include an infrared camera that may measure the presence or absence of a user, a position of the user, and a gaze of the user.

The light module 172 may provide light. The light module 172 may include a light emitting diode or a lamp (e.g., xenon lamp). The light module 172 may be operated in conjunction with the camera module 171 or independently.

The communication module 173 may support the establishment of a wired or wireless communication channel between the electronic device ED and the external electronic device ED-A, and the performance of communication through the established communication channel. The communication module 173 may one or both (e.g., simultaneously) of a wireless communication module, such as a cellular communication module, a short-distance wireless communication module, or a global navigation satellite system (GNSS) communication module, and a wired communication module, such as a local area network (LAN) communication module or a power line communication module. In one or more embodiments, the communication module 173 may communicate with the external electronic device ED-A through a short-range communication network, such as Bluetooth, Wi-Fi direct or infinite data association (IrDA), or a long-distance communication network, such as a cellular network, the Internet, or a computer network (e.g., LAN or WAN). The one or more suitable types (kinds) of communication modules 173 described above may be implemented as a single chip or may be implemented as separate chips.

The input module 130, the sensor module 161, the camera module 171, and/or the like may be used to control the operation of the display module DM in conjunction with the processor 110.

The processor 110 outputs a command or data to the display module DM, the sound output module 163, the camera module 171, and/or the light module 172 based on the input data received from the input module 130. For example, the processor 110 may generate image data in response to input data applied through a mouse or an active pen to output the image data to the display module DM, or may generate command data in response to input data to output the command data to the camera module 171 or the light module 172. When input data is not received from the input module 130 for a specific time, the processor 110 may convert an operation mode of the electronic device ED into a low power mode or a sleep mode to reduce electric power consumed by the electronic device ED.

The processor 110 outputs a command or data to the display module DM, the sound output module 163, the camera module 171, and/or the light module 172 based on the sensing data received from the sensor module 161. For example, the processor 110 may compare authentication data that are applied by the fingerprint sensor 161-1 with authentication data that are stored in the memory 120, and then may execute an application according to the comparison result. The processor 110 may execute a command based on the sensing data sensed by the input sensor 161-2 or the digitizer 161-3 or output corresponding image data to the display module DM. When the sensor module 161 includes a temperature sensor, the processor 110 may receive temperature data on the measured temperature from the sensor module 161, and may further perform a luminance correction on the image data based on the temperature data.

The processor 110 may receive measurement data for the presence or absence of a user, a position of the user, a gaze of the user, and/or the like from the camera module 171. The processor 110 may further perform a luminance correction on image data based on the measurement data. For example, the processor 110 that has determined the presence or absence of a user through an input from the camera module 171 may output image data, of which luminance has been corrected, to the display module DM through the data conversion circuit 112-2 and/or the gamma correction circuit 112-3.

Some of the above components may be connected to each other through a communication method between peripheral devices, for example, a bus, a general purpose input/output (GPIO), a serial peripheral interface (SPI), a mobile industry processor interface (MIPI), or an ultra path interconnect (UPI) link to exchange signals (e.g., a command or data) with each other. The processor 110 may communicate with the display module DM through a promised interface, for example, any one of the above-described communication methods may be used, and is not limited to the above-described communication methods.

The electronic device ED according to one or more embodiments disclosed in this disclosure may be one or more suitable types (kinds) of devices. The electronic device ED may include, for example, at least one of a portable communication device (e.g., a smartphone), a computer device, a portable multimedia device, a portable medical device, a camera, a wearable device, or a home appliance. The electronic device ED according to one or more embodiments of this disclosure is not limited to the above-described devices.

Referring to FIG. 2, the electronic device ED may include a window module WM, a display module DM, and a housing HAU. The window module WM and the housing HAU may be coupled to each other to constitute an exterior of the electronic device ED and protect the display module DM.

The window module WM may include a transmission area TA and a bezel area BZA. The transmission area TA may be an optically transparent area. For example, the transmission area TA may be an area having a visible light transmittance of about 90% or more.

The bezel area BZA may be an area having a relatively lower light transmittance than the transmission area TA. The bezel area BZA may define a shape of the transmission area TA. The bezel area BZA may be adjacent to the transmission area TA, and may be around (e.g., surround) the transmission area TA. However, this is illustrated by way of example, and the bezel area BZA of the window module WM may be partially adjacent to only one side of the transmission area TA, or the bezel area BZA may not be provided from the window module WM. In one or more embodiments, the window module WM may include at least any one functional layer, among an anti-fingerprint layer, a hard coating layer, and an anti-reflection layer, but embodiments of the present disclosure are not limited thereto.

The display module DM may be under (e.g., arranged under) the window module WM. The display module DM may be a configuration for substantially generating an image IM. The image IM may include an image, such as a dynamic image, as well as a static image. The image IM generated by the display module DM may be displayed on the display surface DS of the display module DM, and may be visually recognized by a user from the outside through the transmission area TA.

The housing HAU may be under (e.g., arranged under) the display module DM. The housing HAU may be coupled to the window module WM. The housing HAU may be coupled to the window module WM to provide a specific internal space. The display module DM may be accommodated in the internal space.

The housing HAU may include a material having a relatively high rigidity. For example, the housing HAU may include a plurality of frames and/or plates including glass, plastic, or metal, and/or a (e.g., any suitable) combination thereof. The housing HAU may stably protect the components of the electronic device ED, which are accommodated in the internal space from an external impact.

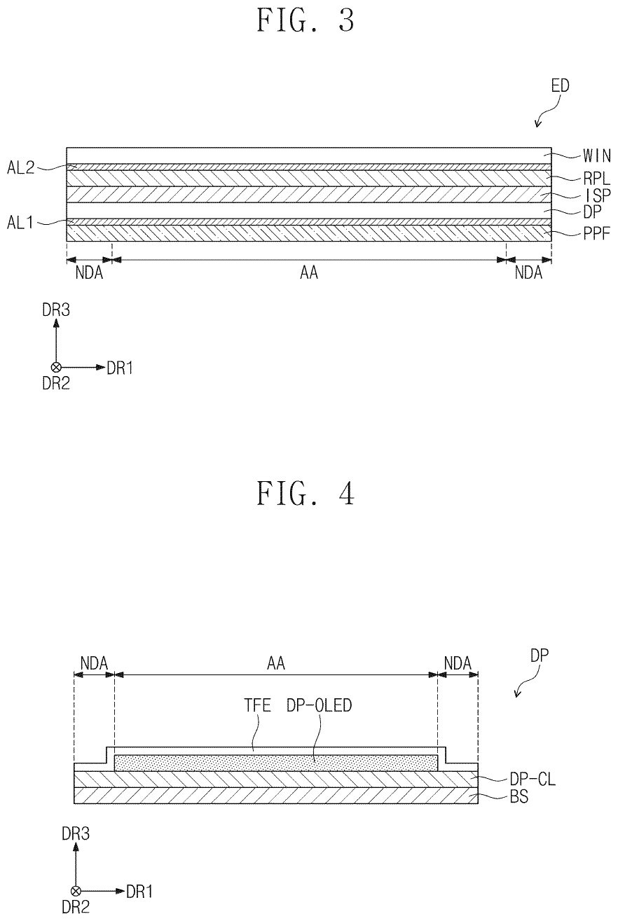

FIG. 3 is a view illustrating a cross section of the electronic device illustrated in FIG. 1A by way of example. FIG. 4 is a view illustrating a cross section of a display panel illustrated in FIG. 3 by way of example.

Referring to FIG. 3, the electronic device ED may include a display panel DP, an input sensing part ISP, an optical layer RPL, a window WIN, a panel protective film PPF, and first and second adhesion layers AL1 and AL2. The display panel DP may correspond to the above-described display panel DP (see FIG. 1B), and the input sensing part ISP may correspond to the above-described sensor module 161 (see FIG. 1B).

The display panel DP according to one or more embodiments of the present disclosure may be a light emitting display panel. For example, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot and/or a quantum rod. Hereinafter, it will be described by way of example that the display panel DP is an organic light emitting display panel.

Referring to FIG. 4, the display panel DP may include a base layer BS, a circuit element layer DP-CL, a display element layer DP-OLED, and a thin film encapsulation layer TFE. The circuit element layer DP-CL, the display element layer DP-OLED, and the thin film encapsulation layer TFE may be sequentially arranged on a base layer BS, for example, in the stated order.

The base layer BS may include glass or may include a flexible plastic material, such as polyimide (PI).

A plurality of pixels may be arranged on the circuit element layer DP-CL and the display element layer DP-OLED. Each of the pixels may include a transistor that is arranged on the circuit element layer DP-CL and a light emitting element that is arranged on the display element layer DP-OLED and is connected to the transistor.

The thin film encapsulation layer TFE may be arranged on the circuit element layer DP-CL to cover the display element layer DP-OLED. The thin film encapsulation layer TFE may protect the pixels from moisture, oxygen, and external foreign substances. In one or more embodiments, it is illustrated that the thin film encapsulation layer TFE covers an entire area of the base layer BS, but in one or more embodiments of the present disclosure, the base layer BS may include a partial area that is exposed from the thin film encapsulation layer TFE. In one or more embodiments, an area exposed from the thin film encapsulation layer TFE may be formed along a periphery of the base layer BS, and embodiments of the present disclosure are not limited thereto.

Referring to FIG. 3, the input sensing part ISP may be arranged on the display panel DP. In one or more embodiments, the input sensing part ISP may include a plurality of sensing parts for sensing an external input in a capacitive manner. The input sensing part ISP may be formed directly on the display panel DP when the electronic device ED is manufactured. In more detail, a conductive pattern and/or an insulating layer that constitutes the input sensing part ISP may be deposited or patterned directly on the display panel DP. However, embodiments of the present disclosure are not limited thereto, and the input sensing part ISP may be manufactured as a separate panel from the display panel DP and attached to the display panel DP through an adhesion layer.

Referring to FIG. 3, the optical layer RPL may be arranged on the input sensing part ISP. The optical layer RPL may reduce an external light reflectance of the electronic device ED to improve a visibility of the image displayed on the electronic device ED. The optical layer RPL may include a phase retarder, a polarizer, a black matrix, a color filter, and/or the like, and is not limited thereto. The optical layer RPL may be formed directly on the input sensing part ISP through a coating or deposition process, or may be provided in the form of a film to be attached to the input sensing part ISP through an adhesion layer, and embodiments of the present disclosure are not limited thereto.

The window WIN may be arranged on the optical layer RPL. The window WIN may protect the display panel DP, the input sensing part ISP, and the optical layer RPL from external scratches and impacts. The window WIN may include an optically transparent insulating material. For example, the window WIN may include glass or plastic.

The panel protective film PPF may be arranged under the display panel DP. The panel protective film PPF may support the display panel DP and protect a lower portion of the display panel DP. The panel protective film PPF may have insulating properties. For example, the panel protective film PPF may include a resin, such as polyethylene terephthalate (PET), polyimide, polypropylene (PP), and/or the like, but embodiments of the present disclosure are not limited thereto.

The first adhesion layer AL1 may be arranged between the display panel DP and the panel protective film PPF, and the display panel DP and the panel protective film PPF may be combined with each other by the first adhesion layer AL1. The second adhesion layer AL2 may be arranged between the window WIN and the optical layer RPL, and the window WIN and the optical layer RPL may be combined with each other by the second adhesion layer AL2.

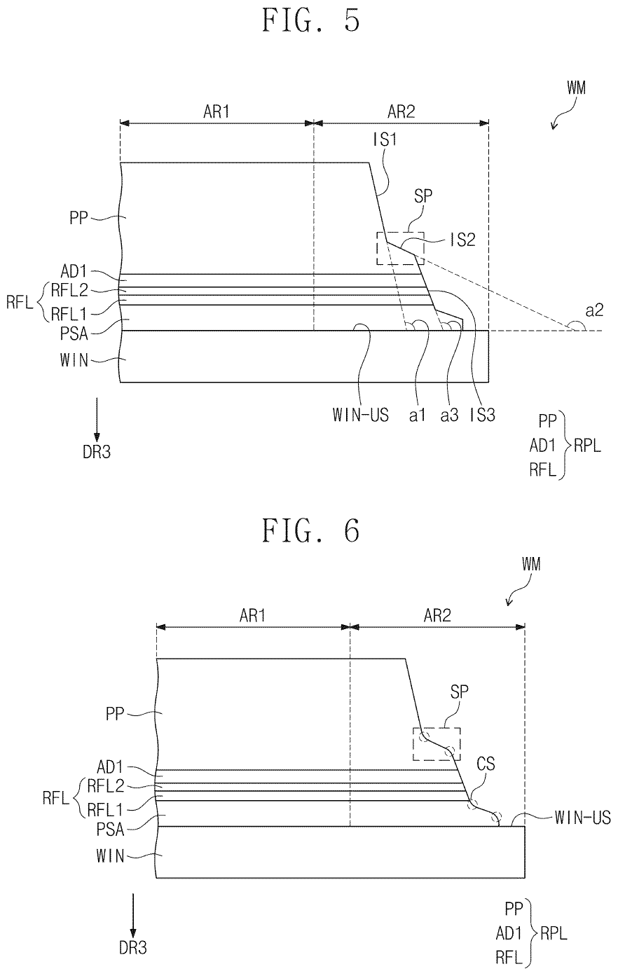

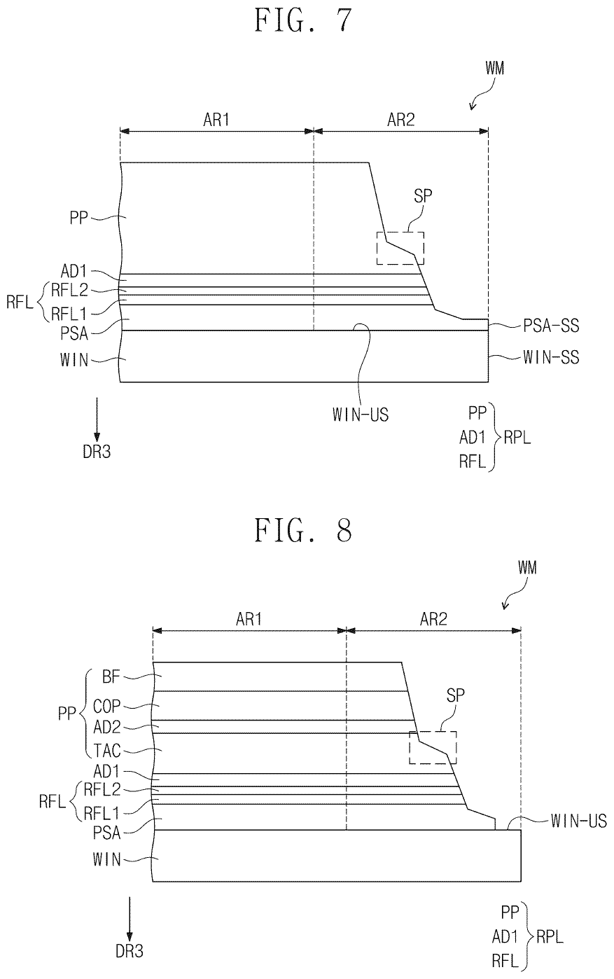

FIG. 5 is an enlarged cross-sectional view illustrating a portion of a window module according to one or more embodiments of the present disclosure. FIG. 6 is an enlarged cross-sectional view illustrating a portion of a window module according to one or more embodiments of the present disclosure. FIG. 7 is an enlarged cross-sectional view illustrating a portion of a window module according to one or more embodiments of the present disclosure. The window modules illustrated in FIGS. 5 to 7 may be rotated by 180 degrees and may be combined with the display panel DP (see FIG. 3).

Referring to FIG. 5, a window module WM may include a window WIN, an adhesion layer PSA, and an optical layer RPL.

The window WIN may be arranged on the display panel DP (see FIG. 3). The window WIN may include a first area AR1 and a second area AR2 that surrounds a periphery of the first area AR1 on a plane (e.g., in plan view). In this regard, each of the first area AR1 and the second area AR2 may respectively correspond to each of the active area AA and the peripheral area NDA illustrated in FIG. 2 after the window module WM is combined with the display panel DP. For example, after the window module WM is combined with the display panel DP, the first area AR1 and the second area AR2 may correspond to the active area AA and the peripheral area NDA illustrated in FIG. 2, respectively.

The optical layer RPL may be arranged on the adhesion layer PSA. The optical layer RPL may be provided in a plurality of layers. The optical layer RPL may include a phase delay layer RFL, a first adhesion member AD1, and a polarizing plate PP. A side surface of the optical layer RPL may be inclined with respect to an upper surface WIN-US of a window WIN. However, embodiments of the present disclosure are not limited thereto, for example, in one or more embodiments, the side surface of the optical layer RPL may be normal (e.g., perpendicular) to the upper surface WIN-US of the window WIN.

The phase delay layer RFL may be arranged on the input sensing part ISP (see FIG. 3). The phase delay layer RFL may include a first phase delay layer RFL1 and a second phase delay layer RFL2. The second phase delay layer RFL2 may be arranged on the first phase delay layer RFL1.

The first phase delay layer RFL1 may be an optical layer that delays a phase of the provided light. For example, the first phase delay layer RFL1 may delay a phase of input light by λ/4. The first phase delay layer RFL1 has optical anisotropy, and may change a polarization state of the light input to the first phase delay layer RFL1. For example, the light that is transmitted through the polarizing plate PP and provided to the first phase delay layer RFL1 may be changed from a linearly polarized state to a circularly polarized state. Furthermore, the light provided to the first phase delay layer RFL1 in a circularly polarized state may be changed to a linearly polarized state.

The second phase delay layer RFL2 may be arranged between the first phase delay layer RFL1 and the polarizing plate PP. The second phase delay layer RFL2 may be an optical layer that delays a phase of the provided light. For example, the second phase delay layer RFL2 may delay a phase of input light by λ/2. The second phase delay layer RFL2 may change a polarization state of the input light. A polarization direction of the linearly polarized light input to the second phase delay layer RFL2 may be changed from the polarizing plate PP.

The polarizing plate PP may prevent or reduce reflection by external light. The polarizing plate PP may shield a portion of the external light. The polarizing plate PP may minimize or reduce reflection by external light in the electronic device ED.

A side surface of the polarizing plate PP may include a stepped part SP. The stepped part SP may overlap the peripheral area NDA. The stepped part SP may include a first surface IS1, a second surface IS2, and a third surface IS3.

In one or more embodiments, the first surface IS1 may be inclined at a first angle a1 with respect to the upper surface WIN-US of the window WIN. The second surface IS2 may be inclined at a second angle a2 with respect to the upper surface WIN-US of the window WIN. The second surface IS2 may be connected to the first surface IS1. In this regard, the second angle a2 may be different from the first angle a1. The third surface IS3 may be inclined at a third angle a3 with respect to the upper surface WIN-US of the window WIN. The third surface IS3 may be connected to the second surface IS2. The third angle a3 may be different from the second angle a2. The first to third surfaces IS1, IS2, and IS3 may each independently include a flat surface. However, embodiments of the present disclosure are not limited thereto.

A side surface of the polarizing plate PP may be spaced and/or apart (e.g., spaced apart or separated) from a side surface of the first adhesion member AD1 by the stepped part SP. In this regard, the side surface of the first adhesion member AD1 may be further spaced and/or apart (e.g., spaced apart or separated) from the first area AR1 than the side surface of the polarizing plate PP. For example, this refers to that the side surface of the first adhesion member AD1 is located at a greater distance from the first area AR1 compared to the side surface of the polarizing plate PP, due to the presence of the stepped part SP.

The first adhesion member AD1 may be arranged between the second phase delay layer RFL2 and the polarizing plate PP. The second phase delay layer RFL2 and the polarizing plate PP may be combined with each other by the first adhesion member AD1.

The adhesion layer PSA may be arranged between the window WIN and the optical layer RPL. In this regard, the adhesion layer PSA may correspond to the second adhesion layer AL2 illustrated in FIG. 3. The window WIN and the optical layer RPL may be combined with each other by the adhesion layer PSA. In one or more embodiments, a side surface of the adhesion layer PSA may be stepped with respect to a side surface of the window WIN. However, embodiments of the present disclosure are not limited thereto.

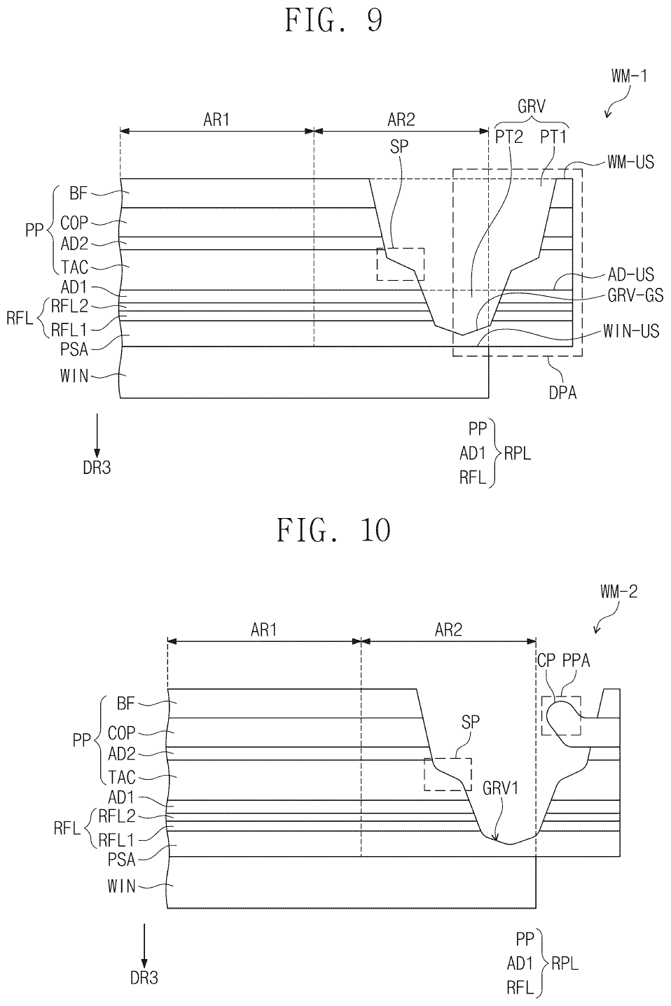

The stepped part SP may be formed by moving in a direction that becomes more distance from the first area AR1 after a first laser irradiation and performing an additional laser irradiation in the window module cutting process that will be described in more detail later. In the case of performing an additional laser irradiation by moving in a direction away from the first area AR1, a dummy part DPA (see FIG. 9) to be removed may be arranged to be further spaced and/or apart (e.g., spaced apart or separated) from the first area AR1 than in the case of performing an additional laser irradiation at the same position after the first laser irradiation. Accordingly, if (e.g., when) the dummy part DPA is removed, damage to the window WIN may be reduced or prevented by reducing an impact that is applied to a portion of the window WIN, which is arranged under the adhesion layer PSA and overlaps the first area AR1.

In one or more embodiments, the optical layer RPL may further include a polarizer layer. The polarizer layer may be an optical layer that linearly polarizes the provided light in one direction, and may be a linearly polarizer. The polarizer layer may be a film type (kind) linearly polarizer including a stretched polymer film. For example, the stretched polymer film may be a stretched polyvinyl alcohol (PVA)-based film.

Referring to FIG. 6, in one or more embodiments, a side surfaces of the polarizing plate PP and a side surface of the adhesion layer PSA may each independently include a curved surface CS. However, the illustrations of FIG. 5 and FIG. 6 are mere examples, and a shape of the side surface of the optical layer RPL may vary depending on a shape of the cross section of cutting during the window module cutting process.

Referring to FIG. 7, unlike FIG. 5 and FIG. 6, in one or more embodiments, a side surface PSA-SS of the adhesion layer PSA and a side surface WIN-SS of the window WIN may be aligned with each other. However, embodiments of the present disclosure are not limited thereto, and a shape of the side surface of the window module WM may vary.

FIG. 8 is an enlarged cross-sectional view illustrating a portion of a window module according to one or more embodiments of the present disclosure. Hereinafter, in a description with reference to FIG. 8, the same/similar reference numerals are used for configurations which are each the same as/similar to those described in FIGS. 5 to 7, and a repeated description thereof will not be provided for conciseness.

Referring to FIG. 8, in one or more embodiments, the polarizing plate PP may be provided in a plurality of layers. The polarizing plate PP may include a triacetylcellulose layer TAC, a second adhesion member AD2, a polyolefin film COP, and a protective film BF.

The triacetylcellulose layer TAC may be arranged on the first adhesion member AD1. The triacetylcellulose layer TAC may protect a polarizer layer that is arranged under the triacetylcellulose layer TAC from an external impact.

The polyolefin film COP may be arranged on the triacetylcellulose layer TAC. The polyolefin film COP may include an optically transparent insulating material.

The second adhesion member AD2 may be arranged between the triacetylcellulose layer TAC and the polyolefin film COP. The triacetylcellulose layer TAC and the polyolefin film COP may be combined with each other by the second adhesion member AD2.

The protective film BF may be arranged on the polyolefin film COP. The protective film BF may protect the polyolefin film COP from an external impact or scratch. Furthermore, the protective film BF may prevent or reduce reflection by external light.

The triacetylcellulose layer TAC may include a stepped part SP that overlaps the second area AR2. The stepped part SP may overlap the peripheral area NDA. A side surface of the polarizing plate PP may be spaced and/or apart (e.g., spaced apart or separated) from a side surface of the first adhesion member AD1 by the stepped part SP. In this regard, the side surface of the first adhesion member AD1 may be further spaced and/or apart (e.g., spaced apart or separated) from the first area AR1 than the side surface of the polarizing plate PP. Although FIG. 8 illustrates that the stepped part SP includes a flat surface, this is only by way of example, the stepped part SP may include a curved surface.

FIG. 9 is an enlarged cross-sectional view illustrating a portion of a window module according to one or more embodiments of the present disclosure. Hereinafter, in a description with reference to FIG. 9, the same/similar reference numerals are used for configurations which are each the same as/similar to those described in FIGS. 5 to 8, and a repeated description thereof will not be provided for conciseness.

Referring to FIG. 9, in one or more embodiments of the present disclosure, a window module WM-1 may include a window WIN, an adhesion layer PSA, and an optical layer RPL. The window module WM-1 illustrated in FIG. 9 may correspond to a window module before an operation of forming the window module WM illustrated in FIG. 8. In one or more embodiments, the optical layer RPL may be provided in a plurality of layers. The optical layer RPL may include a phase delay layer RFL, a first adhesion member AD1, and a polarizing plate PP. The phase delay layer RFL, the first adhesion member AD1, and the polarizing plate PP may correspond to the components illustrated in FIG. 8, respectively, and thus a repeated description thereof will not be provided for conciseness.

In one or more embodiments, a groove GRV may be defined in the window module WM-1. The groove GRV may overlap the second area AR2. The groove GRV may have a shape that is recessed from an upper surface WM-US of the window module WM-1 along a thickness direction of the window module WM-1. The groove GRV may be divided into a first part PT1 and a second part PT2 on a cross section. The first part PT1 may be a space that is formed from the upper surface WM-US of the window module WM-1 to an upper surface AD-US of the first adhesion member AD1, and the second part PT2 may be a space formed from the upper surface AD-US of the first adhesion member AD1 to a bottom surface GRV-GS of the groove GRV. In more detail, the first part PT1 may be formed through a configuration that is stacked on the first adhesion member AD1, that is, in one or more embodiments, may be formed to pass through the polarizing plate PP. For example, the first part PT1 may be formed by removing portions of the protective film BF, the polyolefin film COP, the second adhesion member AD2, and the triacetylcellulose layer TAC. Accordingly, new surfaces of the protective film BF, the polyolefin film COP, the second adhesion member AD2, and the triacetylcellulose layer TAC may be exposed by the first part PT1.

The second part PT2 may be formed to pass through the first adhesion member AD1, and such that a portion of the phase delay layer RFL is recessed. For example, new surfaces of the first adhesion member AD1 and the phase delay layer RFL may be exposed by the second part PT2, but at least a portion of the adhesion layer PSA may still remain to define the bottom surface GRV-GS of the groove GRV. Accordingly, at least a portion of the adhesion layer PSA covers the window WIN, and thus, the upper surface WIN-US of the window WIN may not be exposed through the groove GRV.

A width of the first part PT1 on a cross section may be greater than a width of the second part PT2. For example, a maximum width of the first part PT1 on a cross section may be greater than a maximum width of the second part PT2. In one or more embodiments, in FIG. 9, it is illustrated that a shape of the groove GRV has a symmetrical structure on a cross section, but embodiments of the present disclosure are not limited thereto.

In one or more embodiments, a surface that is exposed by the first part PT1 may include the stepped part SP. The stepped part SP may overlap the second area AR2. The stepped part SP may overlap the peripheral area NDA. A side surface of the polarizing plate PP may be spaced and/or apart (e.g., spaced apart or separated) from a side surface of the first adhesion member AD1 by the stepped part SP. In this regard, the side surface of the first adhesion member AD1 may be further spaced and/or apart (e.g., spaced apart or separated) from the first area AR1 than the side surface of the polarizing plate PP. Although FIG. 9 illustrates that the stepped part SP includes a flat surface, this is by way of example, and, in one or more embodiments, the stepped part SP may include a curved surface. For example, the groove GRV includes the first part PT1 passing through the polarizing plate PP and the second part PT2 passing through the first adhesion member AD1 and the phase delay layer RFL, the second part PT2 exposing at least a portion of the adhesion layer PSA. The first part PT1 includes the at least one stepped part SP.

The window module WM illustrated in FIG. 8 may be formed by removing the dummy part DPA from the window module WM-1 illustrated in FIG. 9. The dummy part DPA overlaps the second area AR2 on a plane, and at least a portion of the dummy part DPA may extend more outward from the side surface of the window WIN. Because the dummy part DPA partially overlaps the second area AR2, a portion of the upper surface WIN-US of the window WIN may be exposed as the dummy part DPA is removed.

The stepped part SP may be formed by moving in a direction that becomes more distance from the first area AR1 after the first laser irradiation and performing an additional laser irradiation in the window module cutting process that will be described in more detail later. After the first laser irradiation, the dummy part DPA may be arranged to be more distant from the first area AR1 when an additional laser irradiation is performed by moving in a direction away from the first area AR1 than when an additional laser irradiation is performed at the same position. Accordingly, if (e.g., when) the dummy part DPA is removed, damage to the window WIN may be reduced or prevented by reducing an impact that is applied to a portion of the window WIN, which is arranged under the adhesion layer PSA and overlaps the first area AR1.

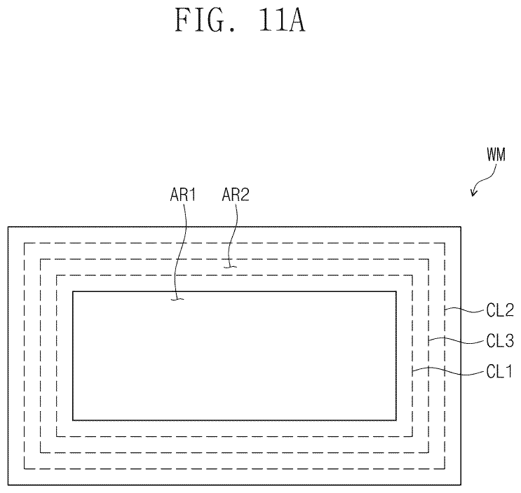

FIG. 10 is an enlarged cross-sectional view illustrating a portion of a window module according to one or more embodiments of the present disclosure. Hereinafter, in a description with reference to FIG. 10, the same/similar reference numerals are used for configurations which are the same as/similar to those described in FIGS. 5 to 9, and a repeated description thereof will not be provided for conciseness.

Referring to FIG. 10, the polarizing plate PP may be provided in a plurality of layers. The polarizing plate PP may include a triacetylcellulose layer TAC, a second adhesion member AD2, a polyolefin film COP, and a protective film BF.

A surface of the polyolefin film COP, which defines a groove GRV1, may include a protruding part PPA. The protruding part PPA may protrude toward an upper surface of the polarizing plate PP. The protruding part PPA may include a curved portion CP. One end of the protruding part PPA may be curved. Accordingly, it is possible to reduce or prevent damage to the window module if (e.g., when) an external force or impact is applied during the laser cutting process by preventing or reducing stress from being concentrated in one point during the window module cutting process. However, embodiments of the present disclosure are not limited thereto, and a shape of the protruding part PPA may be one or more suitable.

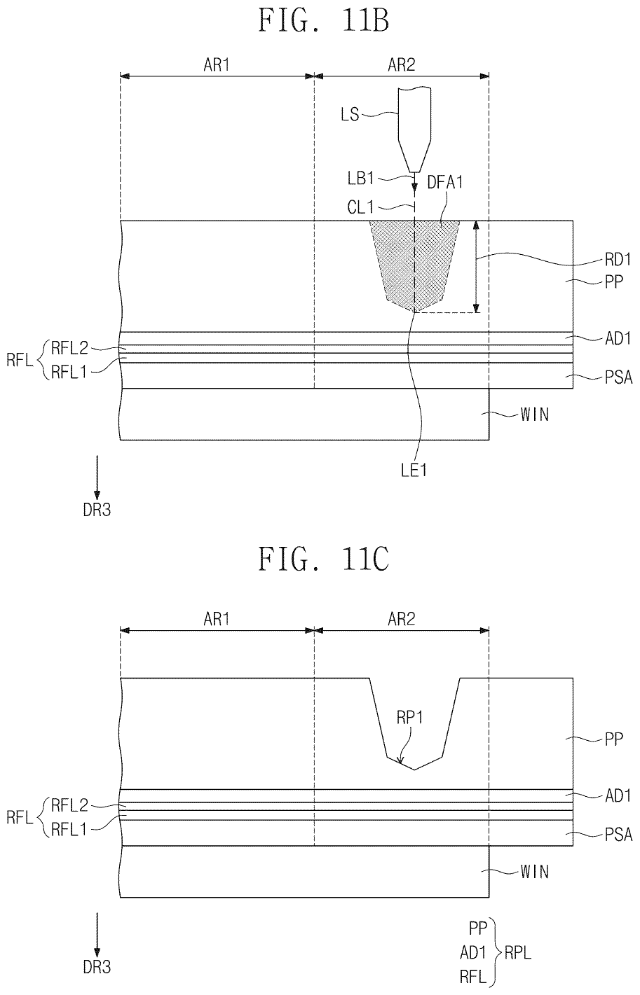

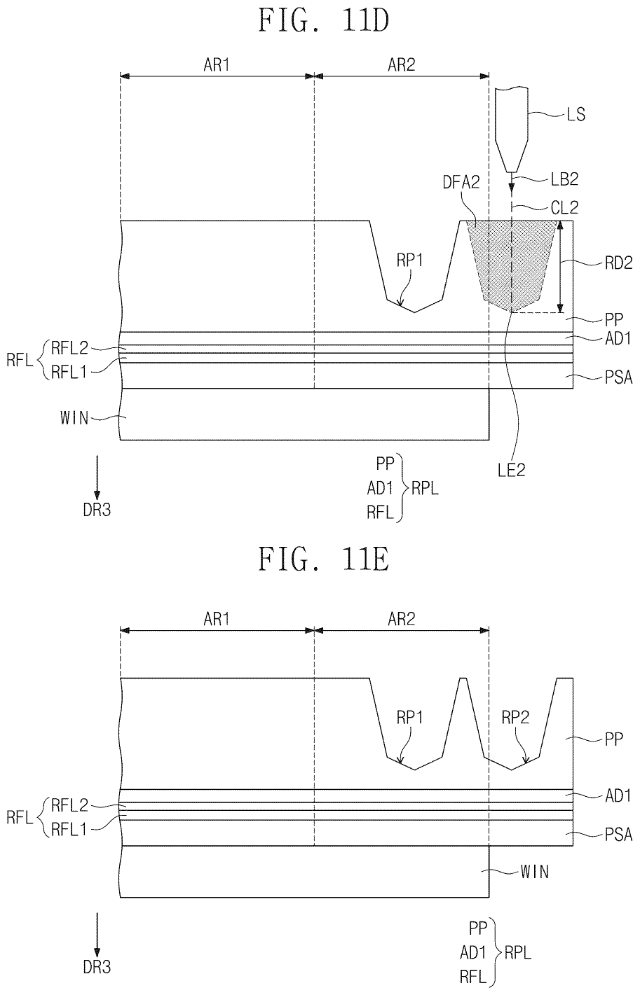

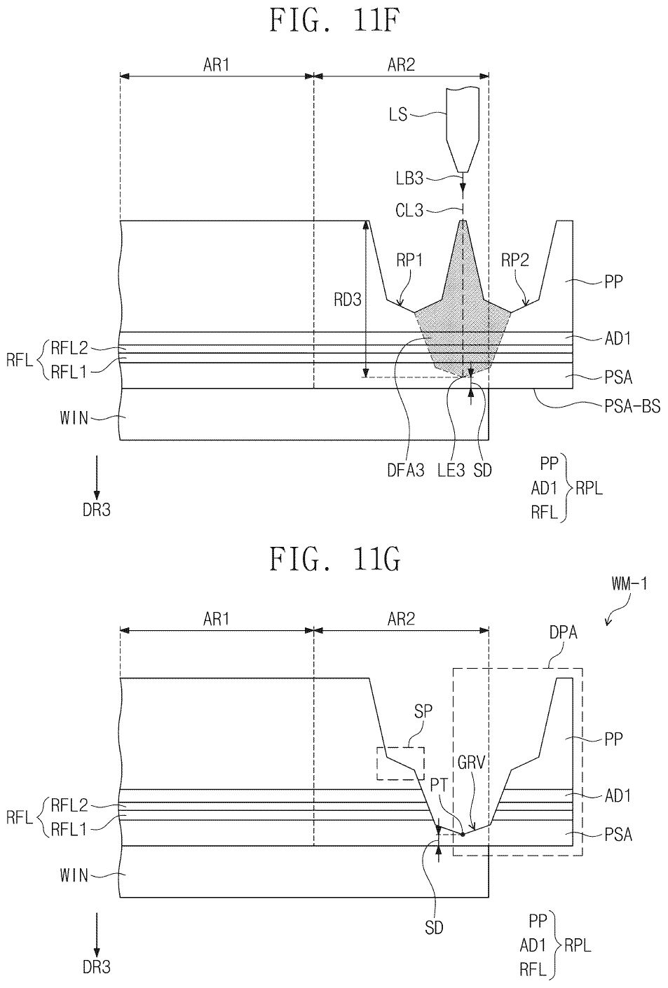

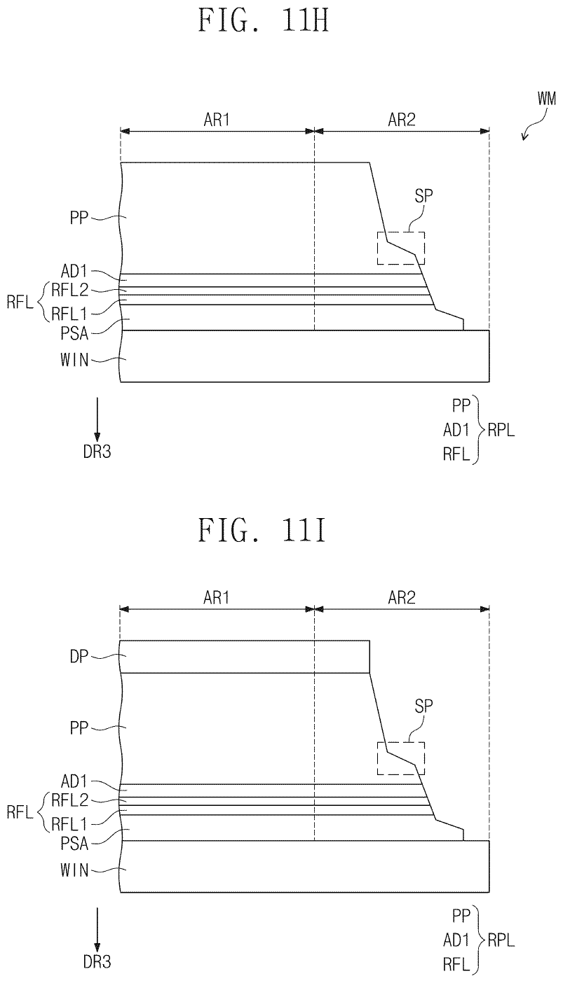

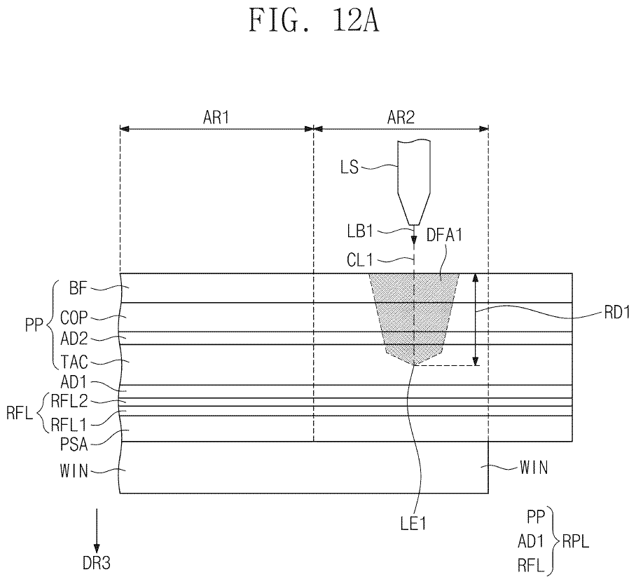

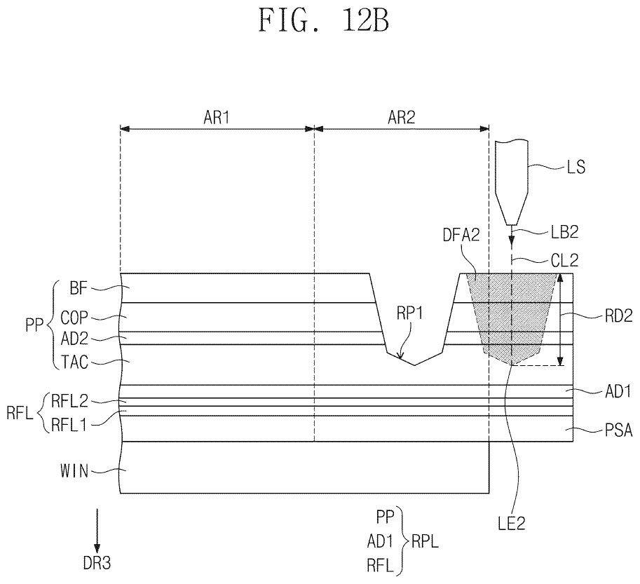

FIG. 11A is a plan view of a window module according to one or more embodiments of the present disclosure. FIGS. 11B to 11I are cross-sectional views illustrating some of operations of a method for manufacturing an electronic device according to one or more embodiments of the present disclosure. Hereinafter, in a description with reference to FIGS. 11A to 11I, the same/similar reference numerals are used for configurations which are the same as/similar to those described in FIGS. 5 to 10, and a repeated description thereof will not be provided for conciseness.

Referring to FIGS. 11A to 11I, a window module may be formed by cutting a preliminary window module. The preliminary window module may be formed by sequentially laminating a window WIN, an adhesion layer PSA, and an optical layer RPL. The window WIN may include a first area AR1, and a second area AR2 that surrounds a periphery of the first area AR1 on a plane. In one or more embodiments, the periphery of each of the first area AR1 and the second area AR2 are illustrated by a solid line for easy description. In these embodiments, the preliminary window module may be cut by a laser beam. An operation of cutting the preliminary window module may include a first irradiation operation, a second irradiation operation, and a third irradiation operation. In one or more embodiments, imaginary irradiation lines CL1, CL2, and CL3 are illustrated by dotted lines for easy description.

FIG. 11B illustrates a first irradiation operation of irradiating a first laser beam LB1 to the preliminary window module.

Referring to FIG. 11A and FIG. 11B, the first laser beam LB1 may be irradiated from a laser irradiation part LS along a first irradiation line CL1. The first irradiation line CL1 may be defined in the second area AR2, and the first laser beam LB1 may be irradiated along the second area AR2 while being spaced and/or apart (e.g., spaced apart or separated) from the first area AR1.

In this regard, the first laser beam LB1 may not reach the phase delay layer RFL and the first adhesion member AD1. For example, the phase delay layer RFL and the first adhesion member AD1 may remain uncut. A depth RD1 (hereinafter, referred to as a first depth) which the first laser beam LB1 reaches may be smaller than a thickness of the polarizing plate PP. In this regard, the first depth RD1 may refer to a length from an upper surface of the polarizing plate PP to an end LE1 of the first irradiation line CL1. The first depth RD1 may be smaller than the thickness of the polarizing plate PP.

If (e.g., when) the laser beam reaches the phase delay layer RFL and a portion of the phase delay layer RFL is cut, a crack may occur in the polarizing plate PP arranged on the phase delay layer RFL. As the first laser beam LB1 does not reach the phase delay layer RFL in one or more embodiments of the present disclosure, the phase delay layer RFL is not cut, thereby preventing a crack from occurring in the polarizing plate PP.

When the first laser beam LB1 is irradiated to the preliminary window module, a deformation may occur in a partial area DFA1 (hereinafter, referred to as a first deformation area) of the preliminary window module, in which the first laser beam LB1 is absorbed. In FIG. 11B, the first deformation area DFA1 is shaded and illustrated for easy description. The deformation generated by the first laser beam LB1 may include a state deformation, such as melting. In this regard, the first deformation area DFA1 may have a width that decreases as a distance from the first laser beam LB1 increases in the thickness direction on a cross section. In the preliminary window module, a deformation at a portion, at which the first laser beam LB1 is first input and is exposed to the first laser beam LB1 for a long time (e.g., for a relatively long period), is most widely generated, and a deformation at a portion, at which the first laser beam LB1 reaches the last and is exposed to the first laser beam LB1 for a relatively short time/period, may be the smallest. Accordingly, the first deformation area DFA1 may have an inverted tapered shape on a cross section. A width of the first deformation area DFA1 on a cross section may be different along a thickness direction. However, embodiments of the present disclosure are not limited thereto.

Referring to FIG. 11B and FIG. 11C, the first deformation area DFA1 may be removed through the first irradiation operation for the preliminary window module. As described above, the first deformation area DFA1 may be a portion of the polarizing plate PP, and may have a thickness that is smaller than that of the polarizing plate PP. Accordingly, a first recessed part RP1 that is recessed in a thickness direction may be formed on the polarizing plate PP.

FIG. 11D illustrates a second irradiation operation of irradiating a second laser beam LB2 to the preliminary window module.

Referring to FIG. 11A and FIG. 11D, a second laser beam LB2 may be irradiated from the laser irradiation part LS along a second irradiation line CL2. The second irradiation line CL2 may be spaced and/or apart (e.g., spaced apart or separated) from the first area AR1 in a direction that becomes more distant from the first area AR1.

In this regard, the second laser beam LB2 may not reach the phase delay layer RFL and the first adhesion member AD1. For example, the phase delay layer RFL and the first adhesion member AD1 may remain uncut. A depth RD2 (hereinafter, referred to as a second depth) which the second laser beam LB2 reaches may be smaller than the thickness of the polarizing plate PP. In this regard, the second depth RD2 may refer to a length from the upper surface of the polarizing plate PP to an end LE2 of the second irradiation line CL2. The second depth RD2 may be smaller than the thickness of the polarizing plate PP. Although FIG. 11D illustrates that the first depth RD1 is substantially the same as the second depth RD2 by way of example, but embodiments of the present disclosure are not limited thereto, and the first and second depths RD1 and RD2 may be different from each other. For example, in one or more embodiments, the second depth RD2 may be greater than the first depth RD1.

When the second laser beam LB2 is irradiated to the preliminary window module, a deformation may occur in a partial area DFA2 (or a second deformation area) of the preliminary window module, in which the second laser beam LB2 is absorbed. In FIG. 11D, the second deformation area DFA2 is shaded and illustrated for easy description. In one or more embodiments, the second deformation area DFA2 may be formed to be spaced and/or apart (e.g., spaced apart or separated) (non-overlap) from a first recessed part RP1 on a plane. However, this is illustrated by way of example, for example, in one or more embodiments, the second area DFA2 may be formed to partially overlap an area, in which the first recessed part RP1 exists, and embodiments of the present disclosure are not limited thereto.

The deformation generated by the second laser beam LB2 may include a state deformation, such as melting. In this regard, the second deformation area DFA2 may have a width that decreases as the distance from the second laser beam LB2 increases in the thickness direction on a cross section. The second deformation area DFA2 may have an inverted tapered shape on a cross section. A width of the second deformation area DFA2 on a cross section may be different along a thickness direction. However, embodiments of the present disclosure are not limited thereto.

The second irradiation operation may be performed after the first irradiation operation. The first laser beam LB1 and the second laser beam LB2 may be laser beams that are irradiated from the same laser irradiation part LS. After cutting a portion of the preliminary window module by irradiating the first laser beam LB1, it may cut another portion of the preliminary window module by moving the preliminary window module in a direction that becomes more distant from the first area AR1 and irradiate the second laser beam LB2.

Referring to FIG. 11D and FIG. 11E, the second deformation area DFA2 may be removed through the second irradiation operation for the preliminary window module. As described above, the second deformation area DFA2 may be a portion of the polarizing plate PP, and may have a thickness that is smaller than that of the polarizing plate PP. Accordingly, a second recessed part RP2 that is recessed in a thickness direction may be formed on the polarizing plate PP.

A distance between the first irradiation line CL1 and the second irradiation line CL2 may be smaller than a half of the diameter of each of the first to third laser beams LB1, LB2, and LB3. If (e.g., when) the distance between the first irradiation line CL1 and the second irradiation line CL2 is greater than a half of the diameter of each of the first to third laser beams LB1, LB2, and LB3, the area of the polarizing plate PP that remains between the first and second recessed parts RP1 and RP2 after the first and second irradiation operations may be relatively large. As a result, it may be difficult to cut the adhesion layer PSA such that a residual thickness SD (see FIG. 11F) of the adhesion layer PSA can be minimized or reduced through a third irradiation operation.

Referring to FIG. 11A and FIG. 11F, a third laser beam LB3 may be irradiated from the laser irradiation part LS along a third irradiation line CL3. The third irradiation line CL3 may be defined in the second area AR2, and the third laser beam LB3 may be irradiated along the second area AR2 while being spaced and/or apart (e.g., spaced apart or separated) from the first area AR1. The third irradiation line CL3 may be defined between the first irradiation line CL1 and the second irradiation line CL2.

In this regard, the third laser beam LB3 may not reach a bottom surface PSA-BS of the adhesion layer PSA. A depth RD3 (hereinafter, referred to as a third depth) which the third laser beam LB3 reaches may be greater than the first depth RD1 and the second depth RD2. In this regard, the third depth RD3 may refer to a length from the upper surface of the polarizing plate PP to an end LE3 of the third irradiation line CL3. The third depth RD3 may be smaller than a depth of the bottom surface of the adhesion layer PSA. In this regard, the depth of the bottom surface of the adhesion layer PSA may refer to a length from the upper surface of the polarizing plate PP to the bottom surface PSA-BS of the adhesion layer PSA. For example, the third laser beam LB3 may not reach the bottom surface PSA-BS of the adhesion layer PSA.

The power of the third laser beam LB3 may be lower than the power of each of the first and second laser beams LB1 and LB2. In the third irradiation operation, the power of the third laser beam LB3 may be set to be lower than the power of each of the first and second laser beams LB1 and LB2, so that the residual thickness SD of the adhesion layer PSA that overlaps the third irradiation line CL3 may be carefully adjusted to be minimized or reduced. Accordingly, when the dummy part DPA is removed, an impact applied to the window WIN may be reduced.

Referring to FIG. 11F, when the third laser beam LB3 is irradiated to the preliminary window module, a deformation may occur in a partial area DFA3 (or the third deformation area) of the preliminary window module. In FIG. 11B, the third deformation area DFA3 is shaded and illustrated for easy description. The deformation generated by the third laser beam LB3 may include a state deformation, such as melting. In this regard, the third deformation area DFA3 may have a width that decreases as the distance from the third laser beam LB3 increases in the thickness direction on a cross section. The third deformation area DFA3 may have an inverted tapered shape on a cross section. A width of the third deformation area DFA3 on a cross section may be different along a thickness direction. However, embodiments of the present disclosure are not limited thereto.

The third irradiation operation may be performed after the second irradiation operation. The first to third laser beams LB1, LB2, and LB3 may be laser beams that are irradiated from the same laser irradiation part LS. After cutting a portion of the preliminary window module by irradiating the second laser beam LB2, the preliminary window module may be moved in a direction that makes the third laser beam LB3 closer to the first area AR1 and be irradiated with the third laser beam LB3, and another portion of the preliminary window module arranged between the first and second irradiation lines CL1 and CL2 may be cut.

Referring to FIG. 11F and FIG. 11G, when the third irradiation operation for a preliminary window module is completed, the third deformation area DFA3 may be removed. As the third deformation area DFA3 between the first recessed part RP1 and the second recessed part RP2 is removed, a groove GRV may be formed in the polarizing plate PP. The groove GRV may overlap the second area AR2. The groove GRV may correspond to the groove GRV illustrated in FIG. 9. The groove GRV may include a stepped part SP. The stepped part SP may overlap the peripheral area NDA. A side surface of the polarizing plate PP may be spaced and/or apart (e.g., spaced apart or separated) from a side surface of the first adhesion member AD1 by the stepped part SP. In this regard, the side surface of the first adhesion member AD1 may be further spaced and/or apart (e.g., spaced apart or separated) from the first area AR1 than the side surface of the polarizing plate PP.

The window module WM illustrated in FIG. 11H may be formed by removing the dummy part DPA from the window module WM-1 illustrated in FIG. 11G. In this regard, the dummy part DPA may be a part that is spaced and/or apart (e.g., spaced apart or separated) from the first area AR1 with respect to a point PT, at which the residual thickness SD of the adhesion layer PSA is minimum. The window module illustrated in FIG. 11H may correspond to the window module illustrated in FIG. 8.

When an additional laser irradiation is performed by irradiating the second laser beam LB2 by moving in a direction away from the first area AR1 from the first laser beam LB1, the dummy part DPA may be formed in a position that is further spaced and/or apart (e.g., spaced apart or separated) from the first area AR1 compared to the case, in which an additional laser irradiation is performed at the same position after the first laser irradiation. Accordingly, when the dummy part DPA is removed, damage to the window WIN may be reduced or prevented by reducing an impact that is applied to a portion of the window WIN, which is arranged under the adhesion layer PSA and overlaps the first area AR1.

Furthermore, as the second and third irradiation lines CL2 and CL3 are set to move away from the first area AR1 from the first irradiation line CL1, the stress between the adhesion layer that is adjacent to the first area AR1 and the window may be minimized or reduced to reduce or prevent damage to the area that is adjacent to the active area AA (see FIG. 2) when the adhesion layer is combined with the display panel of the window WIN, compared to the case of an additional laser irradiation at the same location after the first laser irradiation.

Although FIGS. 11A to 11H illustrate that the number of laser beam irradiation times is three by way of example, embodiments of the present disclosure are not limited thereto, and the number of laser beam irradiation times may vary. Furthermore, the power, speed, focus, and diameters of the first to third laser beams LB1, LB2, and LB3 may be set to be different depending on a material of layers that constitute the window module and a cutting shape of the window module. An interval between the first to third irradiation lines CL3 may also be set to be different depending on a material of the polarizing plate PP.

Referring to FIG. 11I, the window module WM illustrated in FIG. 11H may be combined with a display panel DP. After the display panel DP is arranged on the polarizing plate PP, the window module WM and the display panel DP may be combined with each other. The window module WM and the display panel DP may be pressed to be combined with each other. The first area AR1 and the second area AR2 may correspond to the active area AA (see FIG. 2) and the peripheral area NDA (see FIG. 2), respectively.

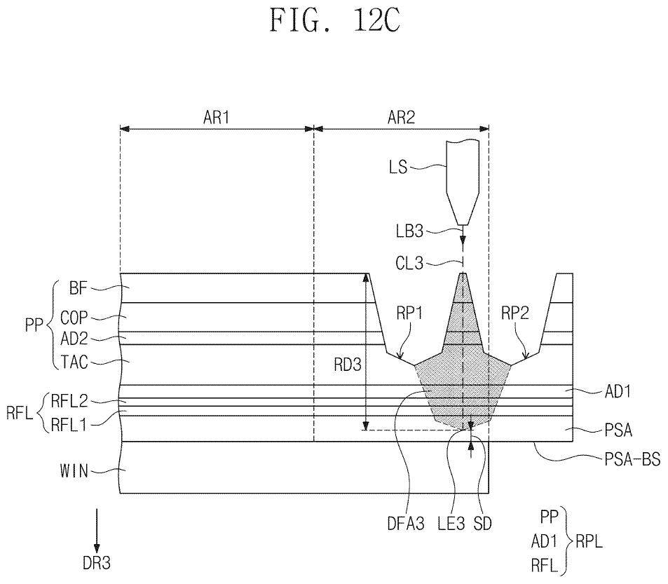

FIGS. 12A to 12C are cross-sectional views illustrating some of operations of a method for manufacturing an electronic device according to one or more embodiments of the present disclosure. Hereinafter, in a description with reference to FIG. 12A and FIG. 12B, the same/similar reference numerals are used for configurations which are the same as/similar to those described in FIGS. 5 to 11I, and a repeated description thereof will not be provided for conciseness.

Referring to FIGS. 12A to 12C, the polarizing plate PP may be provided in a plurality of layers. The polarizing plate PP may include a triacetylcellulose layer TAC, a second adhesion member AD2, a polyolefin film COP, and a protective film BF.

Referring to FIG. 12A, the first laser beam LB1 may pass through the polyolefin film COP and the protective film BF and expose at least a portion of the triacetylcellulose layer TAC. The first depth RD1 may be smaller than a thickness of the polarizing plate PP.

Referring to FIGS. 12A to 12C, in one or more embodiments, the first depth RD1 may correspond to a length that extends from an upper surface of the protective film (BF) to a portion of the triacetylcellulose layer TAC. For example, the first laser beam LB1 may be provided up to a position, in which the first area DFA1 does not reach the first adhesion member AD1 and the phase delay layer RFL. An end LE1 of the first irradiation line CL1 may be arranged on the triacetylcellulose layer TAC. If (e.g., when) the laser beam reaches the phase delay layer RFL and a portion of the phase delay layer RFL is cut, a crack may occur in the polarizing plate PP arranged on the phase delay layer RFL. As the first laser beam LB1 does not reach the phase delay layer RFL, the phase delay layer RFL is not cut, thereby preventing a crack from occurring in the polarizing plate PP.

Similarly, in one or more embodiments, the second depth RD2 may correspond to a length that extends from the upper surface of the protective film BF to a portion of the triacetylcellulose layer TAC. For example, the second laser beam LB2 may be provided up to a position, in which the second area DFA2 does not reach the first adhesion member AD1 and the phase delay layer RFL. An end LE2 of the second irradiation line CL2 may be arranged on the triacetylcellulose layer TAC.

The third depth RD3 may correspond to a length that extends from the upper surface of the protective film BF to a portion of the adhesion layer PSA. For example, the third laser beam LB3 may be provided up to a position, in which the third deformation area DFA3 does not reach the bottom surface PSA-BS of the adhesion layer PSA. The third depth RD3 may be greater than the first depth RD1 and the second depth RD2. An end LE3 of the third irradiation line CL3 may be arranged on the adhesion layer PSA. The third laser beam LB3 may not reach the bottom surface PSA-BS of the adhesion layer PSA. Accordingly, the remaining portion of the uncut adhesion layer PSA may be arranged on the window WIN to protect the window WIN from being damaged by the third laser beam LB3.

When the second and third irradiation operations are performed by moving the first laser beam LB1 in a direction away from the first area AR1, the dummy part DPA (see FIG. 9) may be formed in a position that is further spaced and/or apart (e.g., spaced apart or separated) from the first area AR1, compared to the case, in which the second and third irradiation operations are performed at the same position after the first irradiation operation. Accordingly, when the dummy part DPA is removed, damage to the window WIN may be reduced or prevented by reducing an impact that is applied to a portion of the window WIN, which is arranged under the adhesion layer PSA and overlaps the first area AR1.

According to the present disclosure, an electronic device having an improved reliability may be provided by reducing or preventing a degree of damage to the window when the window module is cut and a crack problem that occurs in the polarizing plate when the dummy part is removed in its window module laser cutting process.

In the present disclosure, expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof.

In the context of the present application and unless otherwise defined, the terms “use,” “using,” and “used” may be considered synonymous with the terms “utilize,”“utilizing,”and “utilized,”respectively.

As utilized herein, the terms “substantially,” “about,” “approximately,” or similar terms are used as terms of approximation and not as terms of degree, and are intended to account for the inherent deviations in measured or calculated values that would be recognized by those of ordinary skill in the art. “About” or “approximately” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” or “approximately” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The window-manufacturing apparatus, the light emitting element, the display module, the display device, the electronic devices/apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the present disclosure has been described with reference to one or more embodiments, it will be appreciated by an ordinary skilled in the art, to which the present disclosure pertains, that the present disclosure may be modified and changed within the scope of the appended claims without departing from the spirits and technical field of the present disclosure. Therefore, the technical scope of the present disclosure should not be limited to the detailed description of the disclosure, but should be determined by the claims and equivalents thereof.

What is claimed is:

1. An electronic device comprising:
a display panel comprising an active area, in which a plurality of pixels is arranged, and a peripheral area being adjacent to the active area;
a window on the display panel;
a housing on a lower side of the display panel and accommodating the display panel;
an optical layer on the window and comprising a plurality of layers; and
an adhesion layer between the window and the optical layer and attaching the window and the optical layer,
wherein the plurality of layers comprises a first layer, a second layer on the first layer, and a third layer on the second layer, and
wherein a side surface of the third layer comprises a stepped part overlapping the peripheral area.

2. The electronic device of claim 1, wherein the stepped part comprises a first surface inclined at a first angle with respect to an upper surface of the window and a second surface inclined at a second angle with respect to the upper surface of the window, the second angle being different from the first angle.

3. The electronic device of claim 2, wherein at least one of the first surface or the second surface comprises a flat surface.

4. The electronic device of claim 2, wherein at least one of the first surface or the second surface comprises a curved surface.

5. The electronic device of claim 2, wherein the stepped part further comprises a third surface connected to the first surface or the second surface, and inclined with respect to the upper surface of the window at a third angle, the third angle being different from an angle of a connected one of the first surface or the second surface with respect to the upper surface of the window.

6. The electronic device of claim 1, wherein the third layer comprises a plurality of layers,
wherein the plurality of layers of the third layer comprises a triacetylcellulose layer, a polyolefin film on the triacetylcellulose layer, and a protective film on the polyolefin film, and
wherein the stepped part is defined on the triacetylcellulose layer.

7. The electronic device of claim 1, wherein a side surface of the second layer is further apart from the active area than a side surface of the first layer.

8. A window module comprising:
a window comprising a first area, and a second area around a periphery of the first area, in plan view;
an optical layer comprising a first layer, a second layer on the first layer, and a third layer on the second layer; and
an adhesion layer between the window and the optical layer and attaching the window and the optical layer,
wherein a groove comprises a first part passing through the third layer and a second part passing through the first layer and the second layer, the second part exposing at least a portion of the adhesion layer, and
wherein the first part comprises at least one stepped part.

9. The window module of claim 8, wherein a width of the first part is greater than a width of the second part, on a cross section.

10. The window module of claim 8, wherein the stepped part comprises a curved surface.

11. The window module of claim 8, wherein a surface of the third layer, which defines the groove, comprises a protruding portion, and
wherein the protruding portion protrudes toward an upper surface of the third layer.

12. A method, comprising:
providing a display panel;
providing a window comprising a first area, and a second area around a periphery of the first area, on a plane;
forming a preliminary window module by sequentially laminating an adhesion layer and an optical layer on the window;
forming a window module by cutting the preliminary window module; and
combining the display panel and the window module,
wherein the forming of the window module by cutting the preliminary window module comprises:
a first irradiation operation of irradiating a first laser beam along a first irradiation line defined in the second area;
a second irradiation operation of irradiating a second laser beam along a second irradiation line spaced apart from the first irradiation line; and
a third irradiation operation of irradiating a third laser beam along a third irradiation line defined between the first irradiation line and the second irradiation line,
wherein the second irradiation line is further apart from the first area than the first irradiation line, and
wherein the method is a method for manufacturing an electronic device.

13. The method of claim 12, wherein the second irradiation operation is progressed after the first irradiation operation, and
wherein the third irradiation operation is progressed after the second irradiation operation.

14. The method of claim 12, wherein a third depth which the third laser beam reaches is greater than a first depth which the first laser beam reaches and a second depth which the second laser beam reaches.

15. The method of claim 14, wherein in the third irradiation operation,
the third depth which the third laser beam reaches is smaller than a depth of a lower surface of the adhesion layer relative to an upper surface of the optical layer.

16. The method of claim 12, wherein the optical layer comprises a phase delay layer, an adhesion member on the phase delay layer, and a polarizing plate on the adhesion member, and
wherein in the first irradiation operation,
the phase delay layer and the adhesion member are not cut.

17. The method of claim 16, wherein in the first irradiation operation, a depth which the first laser beam reaches is smaller than a thickness of the polarizing plate.

18. The method of claim 16, wherein the optical layer comprises a plurality of layers,
wherein the plurality of layers comprises a triacetylcellulose layer, a polyolefin film on the triacetylcellulose layer, and a protective film on the polyolefin film, and
wherein the first laser beam passes through the polyolefin film and the protective film and exposes at least a portion of the triacetylcellulose layer.

19. The method of claim 12, wherein a distance between the first irradiation line and the second irradiation line is smaller than a half of a diameter of each of the first laser beam, the second laser beam, and the third laser beam.

20. The method of claim 12, wherein power of the third laser beam is lower than power of each of the first laser beam and the second laser beam.
